(19) United States
(12) Patent Application Publication
(10) Pub. No.: US 2025/0386427 A1
(43) Pub. Date: Dec. 18, 2025

(54) WIRING CIRCUIT BOARD

(71) Applicant: NITTO DENKO CORPORATION, Osaka (JP)

(72) Inventors: Makiko HIRATA, Osaka (JP); Shusaku SHIBATA, Osaka (JP)

(73) Assignee: NITTO DENKO CORPORATION, Osaka (JP)

(21) Appl. No.: 19/235,241

(22) Filed: Jun. 11, 2025

(30) Foreign Application Priority Data
Jun. 14, 2024 (JP) 2024-096883

(51) Int. Cl. H05K 1/02; H05K 1/18

(52) U.S. Cl. CPC H05K 1/0271; H05K 1/0277; H05K 1/181; H05K 2201/09227; H05K 2201/09727

(57) ABSTRACT

A wiring circuit board includes a wiring portion, and a first support portion supporting one end portion of the wiring portion. A metal support layer of the wiring portion has a first end edge of a one-side end edge and a second end edge of another side end edge. A conductive pattern of the wiring portion has a main body portion disposed away from the first support portion and a first portion disposed between the first support portion and the main body portion. The main body portion has a third end edge of the one-side end edge and a fourth end edge of the other-side end edge. The first portion has a fifth end edge of the one-side end edge and a sixth end edge of the other-side end edge. The fifth end edge is disposed between the third end edge and the first end edge.

### CROSS-REFERENCE TO RELATED APPLICATION

The present application claims priority from Japanese Patent Application No. 2024-96883 filed on Jun. 14, 2024, the contents of which are hereby incorporated by reference into this application.

### TECHNICAL FIELD

The present invention relates to a wiring circuit board.

### BACKGROUND ART

Conventionally, a wiring circuit board including a metal support layer, a base insulating layer disposed on the upper surface of the metal support layer, and a wiring disposed on the upper surface of the base insulating layer has been known (ref: for example, Patent Document 1 below).

### CITATION LIST

### Patent Document

Patent Document 1: Japanese Unexamined Patent Publication No. 2019-212679

### SUMMARY OF THE INVENTION

### Problem to be Solved by the Invention

In the wiring circuit board as described in Patent Document 1, when a first electronic component is moved in a thickness direction of the wiring circuit board with respect to a second electronic component in a state where a first portion of the wiring circuit board is fixed to the first electronic component, and a second portion away from the first portion is fixed to the second electronic component, there is a possibility that the wiring circuit board is curved in the thickness direction of the wiring circuit board in the vicinity of the first portion or the second portion.

Then, the stress is concentrated on a wiring disposed in the curved portion, and there is a possibility that a crack occurs in the wiring.

The present invention provides a wiring circuit board capable of suppressing the occurrence of a crack in a conductive pattern in the vicinity of an end portion of a wiring portion.

### Means for Solving the Problem

The present invention [1] includes a wiring circuit board including a wiring portion extending in a first direction, and a first support portion supporting one end portion of the wiring portion, wherein the wiring portion has a metal support layer, a conductive pattern disposed on one side of the metal support layer in a thickness direction of the metal support layer, and an insulating layer disposed between the metal support layer and the conductive pattern in the thickness direction; the metal support layer has a first end edge of a one-side end edge and a second end edge of another side end edge in a second direction perpendicular to both the thickness direction and the first direction; the conductive pattern has a main body portion disposed away from the first support portion in the first direction and having a third end edge of the one-side end edge and a fourth end edge of the other-side end edge in the second direction, and a first portion disposed between the first support portion and the main body portion in the first direction and connected to the first support portion and having a fifth end edge of the one-side end edge and a sixth end edge of the other-side end edge in the second direction; the third end edge of the main body portion is disposed between a center of the metal support layer and the first end edge of the metal support layer in the second direction; and the fifth end edge of the first portion is disposed between the third end edge and the first end edge in the second direction.

According to such a configuration, the fifth end edge of the first portion is disposed between the third end edge and the first end edge in the second direction. In other words, the fifth end edge of the first portion is disposed closer to the first end edge of the metal support layer than the third end edge of the main body portion in the second direction.

Thus, it is possible to disperse the stress concentrated on the first portion to one side in the second direction with respect to the main body portion.

As a result, it is possible to suppress the concentration of the stress in the vicinity of one end portion of the wiring portion on the first portion, and suppress a crack in the conductive pattern in the vicinity of one end portion of the wiring portion.

The present invention [2] includes the wiring circuit board of the above-described [1], wherein the fourth end edge of the main body portion is disposed between the center of the metal support layer and the second end edge of the metal support layer in the second direction, and the sixth end edge of the first portion is disposed between the fourth end edge and the second end edge in the second direction.

According to such a configuration, the sixth end edge of the first portion is disposed between the fourth end edge and the second end edge in the second direction. In other words, the sixth end edge of the first portion is disposed closer to the second end edge of the metal support layer than the fourth end edge of the main body portion in the second direction.

Thus, it is possible to disperse the stress concentrated on the first portion to the other side in the second direction with respect to the main body portion.

As a result, it is possible to further suppress the concentration of the stress in the vicinity of one end portion of the wiring portion on the first portion, and further suppress the crack in the conductive pattern in the vicinity of one end portion of the wiring portion.

The present invention [3] includes the wiring circuit board of the above-described [1] or [2], wherein the conductive pattern has a wiring, and a width of the wiring in the first portion is wider than the width of the wiring in the main body portion.

According to such a configuration, it is possible to disperse the stress concentrated on the wiring of the first portion by further widening the width of the wiring in the first portion compared to the width of the wiring in the main body portion.

As a result, it is possible to suppress the crack in the wiring in the vicinity of one end portion of the wiring portion.

The present invention [4] includes the wiring circuit board of the above-described [1] or [2], wherein the conductive pattern has a first wiring and a second wiring disposed spaced from the first wiring in the second direction, and an interval between the first wiring and the second wiring in the first portion is wider than the interval between the first wiring and the second wiring in the main body portion.

According to such a configuration, it is possible to disperse the stress concentrated on the wirings (the first wiring and the second wiring) of the first portion by further widening the interval between the first wiring and the second wiring in the first portion compared to the interval between the first wiring and the second wiring in the main body portion.

As a result, it is possible to suppress the crack in the wiring in the vicinity of one end portion of the wiring portion.

The present invention [5] includes the wiring circuit board of the above-described [4], wherein a width of each of the first wiring and the second wiring in the first portion is wider than the width of each of the first wiring and the second wiring in the main body portion.

According to such a configuration, it is possible to disperse the stress concentrated on the wirings (the first wiring and the second wiring) of the first portion by further widening the width of each of the first wiring and the second wiring in the first portion compared to the width of each of the first wiring and the second wiring in the main body portion.

As a result, it is possible to further suppress the crack in the wiring in the vicinity of one end portion of the wiring portion.

The present invention [6] includes the wiring circuit board of any one of the above-described [1] to [5], wherein a thickness of the first portion is thinner than the thickness of the main body portion.

According to such a configuration, it is possible to reduce a bending moment applied to the first portion.

As a result, it is possible to further suppress the crack in the conductive pattern in the vicinity of one end portion of the wiring portion.

The present invention [7] includes the wiring circuit board of any one of the above-described [1] to [6] further including a second support portion supporting the other end portion of the wiring portion, wherein the conductive pattern further has a second portion disposed between the second support portion and the main body portion in the first direction and connected to the second support portion and having a seventh end edge of the one-side end edge and an eighth end edge of the other-side end edge in the second direction; and the seventh end edge of the first portion is disposed between the third end edge and the first end edge in the second direction.

According to such a configuration, the seventh end edge of the second portion is disposed between the third end edge and the first end edge in the second direction. In other words, the seventh end edge of the second portion is disposed closer to the first end edge of the metal support layer than the third end edge of the main body portion in the second direction.

Thus, it is possible to disperse the stress concentrated on the second portion to one side in the second direction with respect to the main body portion.

As a result, it is possible to suppress the concentration of the stress in the vicinity of the other end portion of the wiring portion on the first portion, and suppress the crack in the conductive pattern in the vicinity of the other end portion of the wiring portion.

The present invention [8] includes a wiring circuit board including a wiring portion extending in a first direction and a first support portion supporting one end portion of the wiring portion in the first direction, wherein the wiring portion has an insulating layer and a conductive pattern disposed on one side of the insulating layer in a thickness direction of the insulating layer; the conductive pattern has a main body portion disposed away from the first support portion in the first direction, and a first portion disposed between the first support portion and the main body portion in the first direction and connected to the first support portion; and a thickness of the first portion is thinner than the thickness of the main body portion.

According to such a configuration, it is possible to reduce the bending moment applied to the first portion.

As a result, it is possible to suppress the crack in the conductive pattern in the vicinity of one end portion of the wiring portion.

The present invention [9] includes the wiring circuit board of the above-described [8] further including a second support portion supporting the other end portion of the wiring portion, wherein the conductive pattern further has a second portion disposed between the second support portion and the main body portion in the first direction and connected to the second support portion; and the thickness of the second portion is thinner than the thickness of the main body portion.

According to such a configuration, it is possible to reduce the bending moment applied to the second portion.

As a result, it is possible to suppress the crack in the conductive pattern in the vicinity of the other end portion of the wiring portion.

### Effect of the Invention

According to the wiring circuit board of the present invention, it is possible to suppress the occurrence of the crack in the conductive pattern in the vicinity of the end portion of the wiring portion.

### BRIEF DESCRIPTION OF THE DRAWINGS

FIG. 1 shows a plan view of a first embodiment of a wiring circuit board of the present invention and in FIG. 1, a second insulating layer is omitted.

FIG. 2A shows an A-A cross-sectional view of the wiring circuit board shown in FIG. 1,

FIG. 2B shows a B-B cross-sectional view of the wiring circuit board shown in FIG. 1, and

FIG. 2C shows a C-C cross-sectional view of the wiring circuit board shown in FIG. 1.

FIG. 3 shows an explanatory view for illustrating a mounting state of the wiring circuit board shown in FIG. 2A.

FIG. 4 shows a plan view for illustrating a modified example (1) of the first embodiment.

FIG. 5 shows a plan view for illustrating a modified example (3) of the first embodiment.

FIG. 6 shows a plan view for illustrating a modified example (4) of the first embodiment.

FIG. 7 shows a plan view for illustrating a modified example (5) of the first embodiment.

FIG. 8 shows a plan view for illustrating a modified example (6) of the first embodiment.

FIG. 9 shows a plan view for illustrating a modified example (7) of the first embodiment.

FIG. 10 shows an explanatory view for illustrating a mounting state of the wiring circuit board shown in FIG. 9.

FIG. 11 shows a plan view of a second embodiment of a wiring circuit board of the present invention.

### DESCRIPTION OF EMBODIMENTS

### 1. First Embodiment

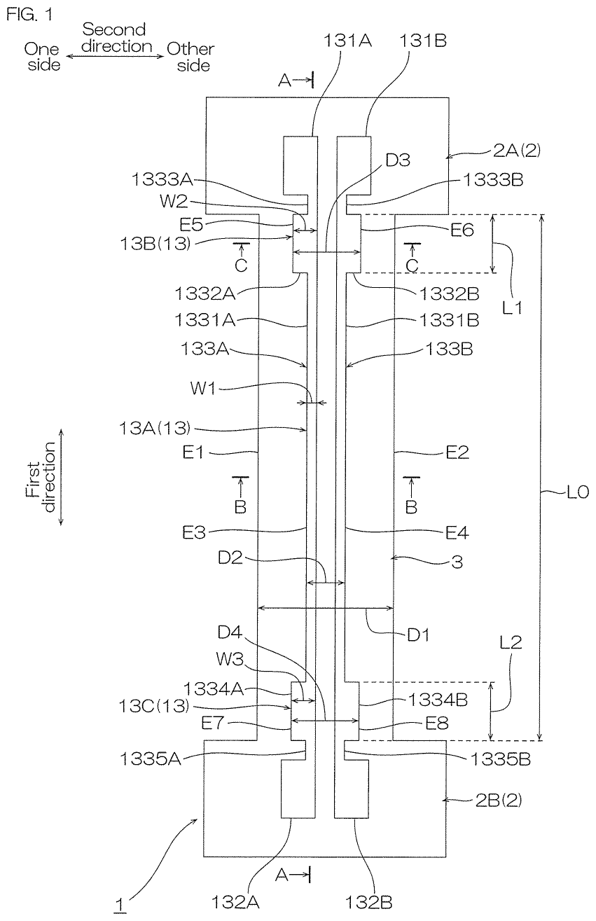

As shown in FIG. 1, a wiring circuit board 1 includes a plurality of support portions 2 (in the present embodiment, a first support portion 2A and a second support portion 2B) and a wiring portion 3.

The first support portion 2A and the second support portion 2B are disposed spaced from each other. A shape of the first support portion 2A and the second support portion 2B is not limited. The first support portion 2A supports one end portion of the wiring portion 3. In the first support portion 2A, terminals 131A and 131B of a conductive pattern 13 to be described later may be also disposed. The second support portion 2B supports the other end portion of the wiring portion 3. In the second support portion 2B, terminals 132A and 132B of the conductive pattern 13 to be described later may be also disposed.

The wiring portion 3 is disposed between the first support portion 2A and the second support portion 2B. The wiring portion 3 extends in a first direction. Specifically, the wiring portion 3 has a width in a second direction, and extends in the first direction. The first direction is a direction in which wirings 133A and 133B of the conductive pattern 13 to be described later extend. The first direction is perpendicular to a thickness direction of the wiring circuit board 1. The second direction is perpendicular to both the thickness direction and the first direction. One end portion of the wiring portion 3 is connected to the first support portion 2A. The other end portion of the wiring portion 3 is connected to the second support portion 2B. The shape of the wiring portion 3 is not limited. The wiring portion 3 may be linear or curved. At least a portion of the wirings 133A and 133B of the conductive pattern 13 to be described later is disposed in the wiring portion 3.

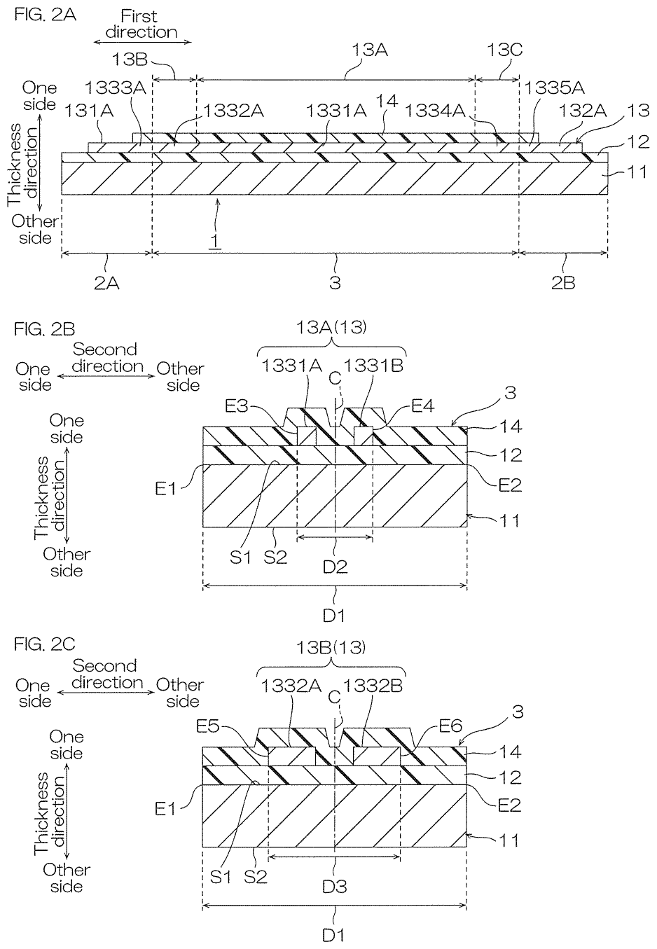

As shown in FIG. 2A, the wiring circuit board 1 has a metal support layer 11, a first insulating layer 12 as one example of an insulating layer, a conductive pattern 13, and a second insulating layer 14.

### (1) Metal Support Layer

The metal support layer 11 is disposed in the support portion 2 (the first support portion 2A and the second support portion 2B) and the wiring portion 3. That is, the wiring portion 3 has the metal support layer 11. The metal support layer 11 supports the first insulating layer 12, the conductive pattern 13, and the second insulating layer 14. The metal support layer 11 is made of metal. Examples of a material for the metal support layer 11 include copper, nickel, cobalt, iron, and alloys of these. Examples of the alloy include copper alloys and stainless steel. As the material for the metal support layer 11, preferably, a copper alloy is used.

A thickness of the metal support layer 11 is, for example, 15 μm to 100 μm, preferably 20 μm to 90 μm.

As shown in FIGS. 2A and 2B, the metal support layer 11 of the wiring portion 3 extends in the first direction and the second direction. Specifically, the metal support layer 11 of the wiring portion 3 has the width in the second direction and extends in the first direction. As shown in FIG. 2B, the metal support layer 11 of the wiring portion 3 has a first end edge E1 and a second end edge E2 in the second direction. The first end edge E1 is a one-side end edge of the metal support layer 11 in the second direction. The second end edge E2 is another side end edge of the metal support layer 11 in the second direction. Specifically, the metal support layer 11 has a first surface S1 and a second surface S2 in the thickness direction. The first surface S1 is a one-side surface of the metal support layer 11 in the thickness direction. The second surface S2 is another side surface of the metal support layer 11 in the thickness direction. The first end edge E1 is the one-side end edge of the first surface S1 in the second direction. The second end edge E2 is the other-side end edge of the first surface S1 in the second direction.

Each of the first end edge E1 and the second end edge E2 extends from one end portion of the wiring portion 3 to the other end portion of the wiring portion 3 in the first direction.

The first surface S1 of the metal support layer 11 may be also covered by a protective metal layer. Examples of the material for the protective metal layer include chromium, nickel, titanium, and alloys of these. The protective metal layer is, for example, a sputtering layer formed by sputtering.

### (2) First Insulating Layer

As shown in FIG. 2A, the first insulating layer 12 is disposed in the support portion 2 (the first support portion 2A and the second support portion 2B) and the wiring portion 3. That is, the wiring portion 3 has the first insulating layer 12. The first insulating layer 12 is disposed on one side of the metal support layer 11 in the thickness direction. The first insulating layer 12 is disposed on the first surface S1 of the metal support layer 11 in the thickness direction. The first insulating layer 12 is disposed between the metal support layer 11 and the conductive pattern 13 in the thickness direction. The first insulating layer 12 insulates the metal support layer 11 from the conductive pattern 13. The first insulating layer 12 is made of a resin. Examples of the resin include polyimide, maleimide, epoxy resins, polybenzoxazole, and polyester. Preferably, the first insulating layer 12 is made of polyimide.

The thickness of the first insulating layer 12 is, for example, 1 μm to 30 μm, preferably 3 μm to 25 μm.

### (3) Conductive Pattern

The conductive pattern 13 is disposed on one side of the first insulating layer 12 in the thickness direction. The conductive pattern 13 is disposed on the one-side surface of the first insulating layer 12 in the thickness direction. The conductive pattern 13 is disposed at the opposite side of the metal support layer 11 with respect to the first insulating layer 12 in the thickness direction. The conductive pattern 13 is made of metal. Examples of the metal include copper, silver, gold, iron, aluminum, chromium, and alloys of these. From the viewpoint of obtaining excellent electrical properties, preferably, copper is used. The shape of the conductive pattern 13 is not limited.

As shown in FIG. 1, the conductive pattern 13 is disposed in the support portion 2 (the first support portion 2A and the second support portion 2B) and the wiring portion 3. That is, the wiring portion 3 has the conductive pattern 13. In the wiring portion 3, the conductive pattern 13 has a main body portion 13A, a first portion 13B, and a second portion 13C.

### (3-1) Main Body Portion

The main body portion 13A is disposed away from the first support portion 2A in the first direction. As shown in FIG. 2B, the main body portion 13A has a third end edge E3 and a fourth end edge E4 in the second direction. The third end edge E3 is the one-side end edge of the main body portion 13A in the second direction. The third end edge E3 is disposed between a center C of the metal support layer 11 and the first end edge E1 of the metal support layer 11 in the second direction. The fourth end edge E4 is the other-side end edge of the main body portion 13A in the second direction. The fourth end edge E4 of the main body portion 13A is disposed between the center C of the metal support layer 11 and the second end edge E2 of the metal support layer 11 in the second direction.

A distance D2 between the third end edge E3 and the fourth end edge E4 in the second direction is shorter than a distance D1 between the first end edge E1 and the second end edge E2 in the second direction. A ratio (D2/D1) of the distance D2 to the distance D1 is, for example, 90/100 or less, preferably 50/100 or less. The ratio (D2/D1) is, for example, 5/100 or more.

### (3-2) First Portion

As shown in FIG. 1, the first portion 13B is disposed in one end portion of the wiring portion 3. The first portion 13B is disposed between the first support portion 2A and the main body portion 13A in the first direction. The first portion 13B is connected to the first support portion 2A.

In the first direction, a length L1 of the first portion 13B is, for example, 0.1% to 25%, preferably 1% to 25%, more preferably 5% to 25% of a total length L0 of the wiring portion 3.

As shown in FIG. 2C, the first portion 13B has a fifth end edge E5 and a sixth end edge E6 in the second direction. The fifth end edge E5 is the one-side end edge of the first portion 13B in the second direction. The fifth end edge E5 is disposed between the third end edge E3 (ref: FIG. 2B) and the first end edge E1 in the second direction. The sixth end edge E6 is the other-side end edge of the first portion 13B in the second direction. The sixth end edge E6 is disposed between the fourth end edge E4 (ref: FIG. 2B) and the second end edge E2 in the second direction.

A distance D3 between the fifth end edge E5 and the sixth end edge E6 in the second direction is shorter than the distance D1 between the first end edge E1 and the second end edge E2 in the second direction. The distance D3 is longer than the distance D2 between the third end edge E3 and the fourth end edge E4 in the second direction (ref: FIG. 2B). The ratio (D3/D1) of the distance D3 to the distance D1 is larger than the ratio (D2/D1) of the distance D2 to the distance D1. The ratio (D3/D1) is, for example, 10/100 or more, preferably 60/100 or more. The ratio (D3/D1) is, for example, 100/100 or less.

### (3-3) Second Portion

As shown in FIG. 1, the second portion 13C is disposed in the other end portion of the wiring portion 3. The second portion 13C is disposed between the second support portion 2B and the main body portion 13A in the first direction. The second portion 13C is connected to the second support portion 2B.

In the first direction, a length L2 of the second portion 13C is, for example, 0.1% to 25%, preferably 1% to 25%, more preferably 5% to 25% of the total length L0 of the wiring portion 3. The length L2 of the second portion 13C may be also the same as the length L1 of the first portion 13B. The length L2 of the second portion 13C may be also different from the length L1 of the first portion 13B.

The second portion 13C has a seventh end edge E7 and an eighth end edge E8 in the second direction. The seventh end edge E7 is the one-side end edge of the second portion 13C in the second direction. The seventh end edge E7 is disposed between the third end edge E3 and the first end edge E1 in the second direction. The eighth end edge E8 is the other-side end edge of the second portion 13C in the second direction. The eighth end edge E8 is disposed between the fourth end edge E4 and the second end edge E2 in the second direction.

A distance D4 between the seventh end edge E7 and the eighth end edge E8 in the second direction is shorter than the distance D1 between the first end edge E1 and the second end edge E2 in the second direction. The distance D4 is longer than the distance D2 between the third end edge E3 and the fourth end edge E4 in the second direction. The distance D4 may be also the same as the distance D3 between the fifth end edge E5 and the sixth end edge E6 in the second direction. The distance D4 may be also different from the distance D3. The ratio (D4/D1) of the distance D4 to the distance D1 is larger than the ratio (D2/D1) of the distance D2 to the distance D1. The ratio (D4/D1) of the distance D4 to the distance D1 may be also the same as the ratio (D3/D1) of the distance D3 to the distance D1. The ratio (D4/D1) may be also different from the ratio (D3/D1). The ratio (D4/D1) is, for example, 10/100 or more, preferably 60/100 or more. The ratio (D4/D1) is, for example, 100/100 or less.

### (3-4) Details of Conductive Pattern

The conductive pattern 13 has the plurality of terminals 131A and 131B, the plurality of terminals 132A and 132B, and the plurality of wirings 133A and 133B.

### (3-4-1) Terminal

The terminals 131A and 131B are disposed in the first support portion 2A. Each of the terminals 131A and 131B has a generally rectangular shape. In the present embodiment, the terminals 131A and 131B are aligned in the second direction. The terminals 131A and 131B are disposed spaced from each other in the second direction. The direction in which the terminals 131A and 131B are aligned is not limited to the second direction.

The terminals 132A and 132B are disposed in the second support portion 2B. Each of the terminals 132A and 132B has the generally rectangular shape. The terminals 132A and 132B are aligned in the second direction. The terminals 132A and 132B are disposed spaced from each other in the second direction. The direction in which the terminals 132A and 132B are aligned is not limited to the second direction.

### (3-4-2) Wiring

At least a portion of each of the wirings 133A and 133B is disposed in the wiring portion 3. That is, the conductive pattern 13 of the wiring portion 3 has the wiring 133A as one example of a first wiring and the wiring 133B as one example of a second wiring. Each of the wirings 133A and 133B extends in the first direction in the wiring portion 3. The wirings 133A and 133B are aligned in the second direction in the wiring portion 3. The wirings 133A and 133B are disposed spaced from each other in the second direction.

The wiring 133A electrically connects the terminal 131A to the terminal 132A. One end portion of the wiring 133A is connected to the terminal 131A. The other end portion of the wiring 133A is connected to the terminal 132A. The wiring 133A is disposed between the center C of the metal support layer 11 (ref: FIGS. 2A and 2B) and the first end edge E1 of the metal support layer 11 (ref: FIGS. 2A and 2B) in the second direction. Of the plurality of wirings 133A and 133B, the wiring 133A is closest to the first end edge E1 in the second direction. In the present embodiment, the wiring 133A has a main body portion 1331A, a first wide portion 1332A, a first connecting portion 1333A, a second wide portion 1334A, and a second connecting portion 1335A.

The main body portion 1331A is disposed in the main body portion 13A of the conductive pattern 13. The one-side end edge of the main body portion 1331A in the second direction is the third end edge E3 of the main body portion 13A.

The first wide portion 1332A is disposed in the first portion 13B of the conductive pattern 13. The one-side end edge of the first wide portion 1332A in the second direction is the fifth end edge E5 of the first portion 13B. A width W2 (dimension in the second direction) of the first wide portion 1332A is wider than a width W1 of the main body portion 1331A.

The first connecting portion 1333A is disposed in the first support portion 2A. The first connecting portion 1333A is disposed between the first wide portion 1332A and the terminal 131A. The first connecting portion 1333A is connected to the terminal 131A. In the present embodiment, the width of the first connecting portion 1333A is the same as the width W1 of the main body portion 1331A. The width of the first connecting portion 1333A may be also the same as the width W2 of the first wide portion 1332A.

The second wide portion 1334A is disposed in the second portion 13C of the conductive pattern 13. The one-side end edge of the second wide portion 1334A in the second direction is the seventh end edge E7 of the second portion 13C. A width W3 of the second wide portion 1334A is wider than the width W1 of the main body portion 1331A. The width W3 of the second wide portion 1334A may be also the same as the width W2 of the first wide portion 1332A. The width W3 of the second wide portion 1334A may be also different from the width W2 of the first wide portion 1332A.

The second connecting portion 1335A is disposed in the second support portion 2B. The second connecting portion 1335A is disposed between the second wide portion 1334A and the terminal 132A. The second connecting portion 1335A is connected to the terminal 132A. In the present embodiment, the width of the second connecting portion 1335A is the same as the width W1 of the main body portion 1331A. The width of the second connecting portion 1335A may be also the same as the width W3 of the second wide portion 1334A.

The wiring 133B electrically connects the terminal 131B to the terminal 132B. One end portion of the wiring 133B is connected to the terminal 131B. The other end portion of the wiring 133B is connected to the terminal 132B. The wiring 133B is disposed spaced from the wiring 133A in the second direction. The wiring 133B is disposed between the center C of the metal support layer 11 (ref: FIGS. 2A and 2B) and the second end edge E2 of the metal support layer 11 (ref: FIGS. 2A and 2B) in the second direction. Of the plurality of wirings 133A and 133B, the wiring 133B is the closest to the second end edge E2 in the second direction. In the present embodiment, the wiring 133B has a main body portion 1331B, a first wide portion 1332B, a first connecting portion 1333B, a second wide portion 1334B, and a second connecting portion 1335B.

The main body portion 1331B is disposed in the main body portion 13A of the conductive pattern 13. The other-side end edge of the main body portion 1331B in the second direction is the fourth end edge E4 of the main body portion 13A.

The first wide portion 1332B is disposed in the first portion 13B of the conductive pattern 13. The other-side end edge of the first wide portion 1332B in the second direction is the sixth end edge E6 of the first portion 13B. The width of the first wide portion 1332B is wider than the width of the main body portion 1331B.

The first connecting portion 1333B is disposed in the first support portion 2A. The first connecting portion 1333B is disposed between the first wide portion 1332B and the terminal 131B. The first connecting portion 1333B is connected to the terminal 131B. In the present embodiment, the width of the first connecting portion 1333B is the same as the width of the main body portion 1331B. The width of the first connecting portion 1333B may be also the same as the width of the first wide portion 1332B.

The second wide portion 1334B is disposed in the second portion 13C of the conductive pattern 13. The other-side end edge of the second wide portion 1334B in the second direction is the eighth end edge E8 of the second portion 13C. The width of the second wide portion 1334B is wider than the width of the main body portion 1331B. The width of the second wide portion 1334B may be also the same as the width of the first wide portion 1332B. The width of the second wide portion 1334B may be also different from the width of the first wide portion 1332B.

The second connecting portion 1335B is disposed in the second support portion 2B. The second connecting portion 1335B is disposed between the second wide portion 1334B and the terminal 132B. The second connecting portion 1335B is connected to the terminal 132B. In the present embodiment, the width of the second connecting portion 1335B is the same as the width of the main body portion 1331B. The width of the second connecting portion 1335B may be also the same as the width of the second wide portion 1334B.

### (4) Second Insulating Layer

As shown in FIG. 2B, the second insulating layer 14 covers all of the wirings 133A and 133B. The second insulating layer 14 is disposed on the first insulating layer 12 in the thickness direction. As shown in FIG. 2A, the second insulating layer 14 does not cover the terminals 131A, 131B, 132A, and 132B. The second insulating layer 14 is made of a resin. Examples of the resin include polyimide, maleimide, epoxy resins, polybenzoxazole, and polyester. Preferably, the second insulating layer 14 is made of polyimide.

### 2. Mounting State of Wiring Circuit Board

Next, a mounting state of the wiring circuit board 1 is described.

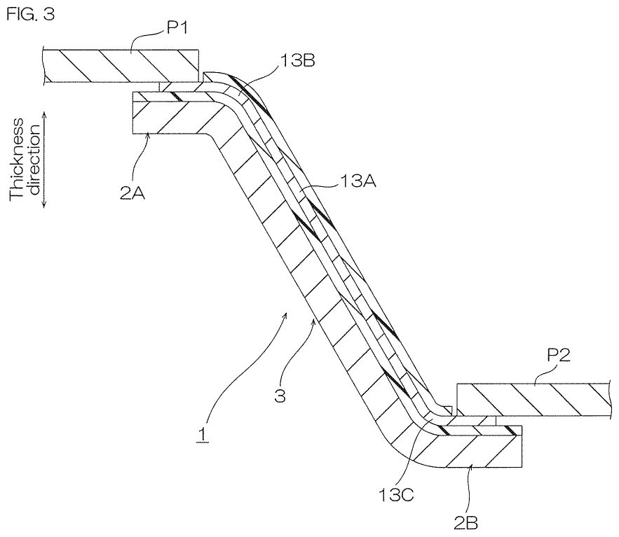

As shown in FIG. 3, the wiring circuit board 1 is fixed to an electronic component in the support portion 2. For example, the first support portion 2A is fixed to a first electronic component P1, and the second support portion 2B is fixed to a second electronic component P2. The wiring portion 3 is disposed between the first electronic component P1 and the second electronic component P2.

Then, when the first electronic component P1 is moved in the thickness direction of the wiring circuit board 1 with respect to the second electronic component P2, one end portion of the wiring portion 3 and the other end portion of the wiring portion 3 are bent in the thickness direction.

At this time, the stress in the vicinity of one end portion of the wiring portion 3 is concentrated on the first portion 13B. Further, the stress in the vicinity of the other end portion of the wiring portion 3 is concentrated on the second portion 13C.

In this point, as shown in FIG. 1, in the conductive pattern 13, the fifth end edge E5 of the first portion 13B is disposed closer to the first end edge E1 of the metal support layer 11 than the third end edge E3 of the main body portion 13A in the second direction. Thus, it is possible to disperse the stress concentrated on the wiring 133A to one side in the second direction with respect to the main body portion 13A.

Similarly, the sixth end edge E6 of the first portion 13B is disposed closer to the second end edge E2 of the metal support layer 11 than the fourth end edge E4 of the main body portion 13A in the second direction. Thus, it is possible to disperse the stress concentrated on the wiring 133B to the other side in the second direction with respect to the main body portion 13A.

As a result, it is possible to suppress the concentration of the stress in the vicinity of the end portion of the wiring portion 3 on the wirings 133A and 133B, and suppress a crack in the wirings 133A and 133B in the vicinity of the end portion of the wiring portion 3.

### 3. Function and Effect

(1) According to the wiring circuit board 1, as shown in FIG. 1, the fifth end edge E5 of the first portion 13B is disposed between the third end edge E3 and the first end edge E1 in the second direction. In other words, the fifth end edge E5 of the first portion 13B is disposed closer to the first end edge E1 of the metal support layer 11 than the third end edge E3 of the main body portion 13A in the second direction.

Thus, it is possible to disperse the stress concentrated on the first portion 13B to one side in the second direction with respect to the main body portion 13A.

As a result, it is possible to suppress the concentration of the stress in the vicinity of one end portion of the wiring portion 3 on the first portion 13B, and suppress the crack in the conductive pattern 13 in the vicinity of one end portion of the wiring portion 3.
(2) According to the wiring circuit board 1, as shown in FIG. 1, the sixth end edge E6 of the first portion 13B is disposed between the fourth end edge E4 and the second end edge E2 in the second direction. In other words, the sixth end edge E6 of the first portion 13B is disposed closer to the second end edge E2 of the metal support layer 11 than the fourth end edge E4 of the main body portion 13A in the second direction.

Thus, it is possible to disperse the stress concentrated on the first portion 13B to the other side in the second direction with respect to the main body portion 13A.

As a result, it is possible to further suppress the concentration of the stress in the vicinity of one end portion of the wiring portion 3 on the first portion 13B, and further suppress the crack in the conductive pattern 13 in the vicinity of one end portion of the wiring portion 3.
(3) According to the wiring circuit board 1, as shown in FIG. 1, the conductive pattern 13 of the wiring portion 3 has the wirings 133A and 133B, and the width W2 of each of the wirings 133A and 133B in the first portion 13B is wider than the width W1 of each of the wirings 133A and 133B in the main body portion 13A.

Therefore, it is possible to disperse the stress concentrated on each of the wirings 133A and 133B of the first portion 13B by further widening the width W2 of each of the wirings 133A and 133B in the first portion 13B compared to the width W1 of each of the wirings 133A and 133B in the main body portion 13A.

As a result, it is possible to suppress the crack in the wirings 133A and 133B in the vicinity of one end portion of the wiring portion 3.
(4) According to the wiring circuit board 1, as shown in FIG. 1, the seventh end edge E7 of the second portion 13C is disposed between the third end edge E3 and the first end edge E1 in the second direction. In other words, the seventh end edge E7 of the second portion 13C is disposed closer to the first end edge E1 of the metal support layer 11 than the third end edge E3 of the main body portion 13A in the second direction.

Thus, it is possible to disperse the stress concentrated on the second portion 13C to one side in the second direction with respect to the main body portion 13A.

As a result, it is possible to suppress the concentration of the stress in the vicinity of the other end portion of the wiring portion 3 on the second portion 13C, and suppress the crack in the conductive pattern 13 in the vicinity of the other end portion of the wiring portion 3.

### 4. Modified Examples of First Embodiment

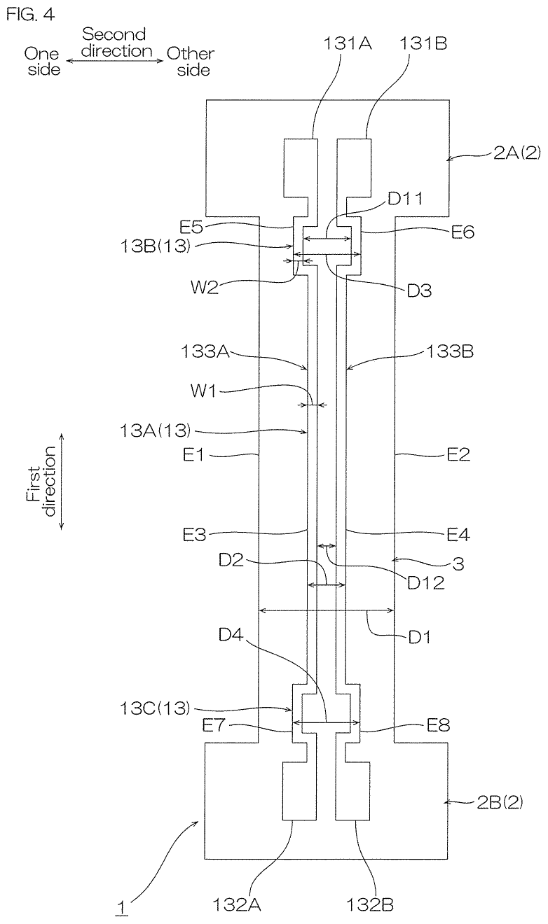

Modified examples of a first embodiment are described. In each modified example, the same reference numerals are provided for members corresponding to each of those in the first embodiment, and their detailed description is omitted.
(1) As shown in FIG. 4, an interval D11 between the wiring 133A and the wiring 133B in the first portion 13B may be also wider than an interval D12 between the wiring 133A and the wiring 133B in the main body portion 13A. In this case, the width W2 of each of the wirings 133A and 133B in the first portion 13B may be also the same as the width W1 of each of the wirings 133A and 133B in the main body portion 13A.

According to this modified example, it is possible to disperse the stress concentrated on the wirings 133A and 133B of the first portion 13B by further widening the interval D11 between the wiring 133A and the wiring 133B in the first portion 13B compared to the interval D12 between the wiring 133A and the wiring 133B in the main body portion 13A.

As a result, it is possible to suppress the crack in the wirings 133A and 133B in the vicinity of the end portion of the wiring portion 3.
(2) In the above-described modified example (1), the width W2 of each of the wirings 133A and 133B in the first portion 13B may be also wider than the width W1 of each of the wirings 133A and 133B in the main body portion 13A.

According to this modified example, it is possible to disperse the stress concentrated on the wirings 133A and 133B of the first portion 13B by further widening the width W2 of each of the wirings 133A and 133B in the first portion 13B compared to the width W1 of each of the wirings 133A and 133B in the main body portion 13A.

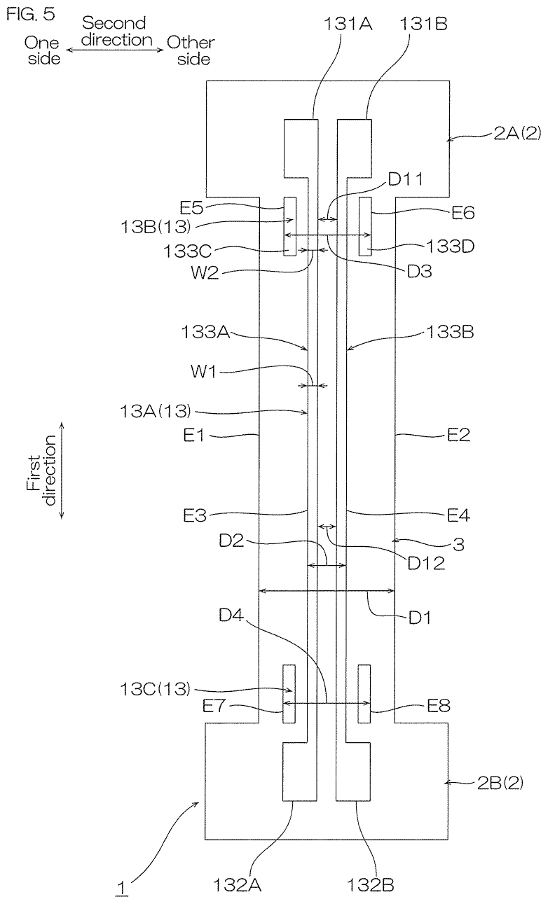

As a result, it is possible to further suppress the crack in the wirings 133A and 133B in the vicinity of the end portion of the wiring portion 3.
(3) As shown in FIG. 5, the interval D11 between the wiring 133A and the wiring 133B in the first portion 13B may be also the same as the interval D12 between the wiring 133A and the wiring 133B in the main body portion 13A, and the width W2 of each of the wirings 133A and 133B in the first portion 13B may be also the same as the width W1 of each of the wirings 133A and 133B in the main body portion 13A.

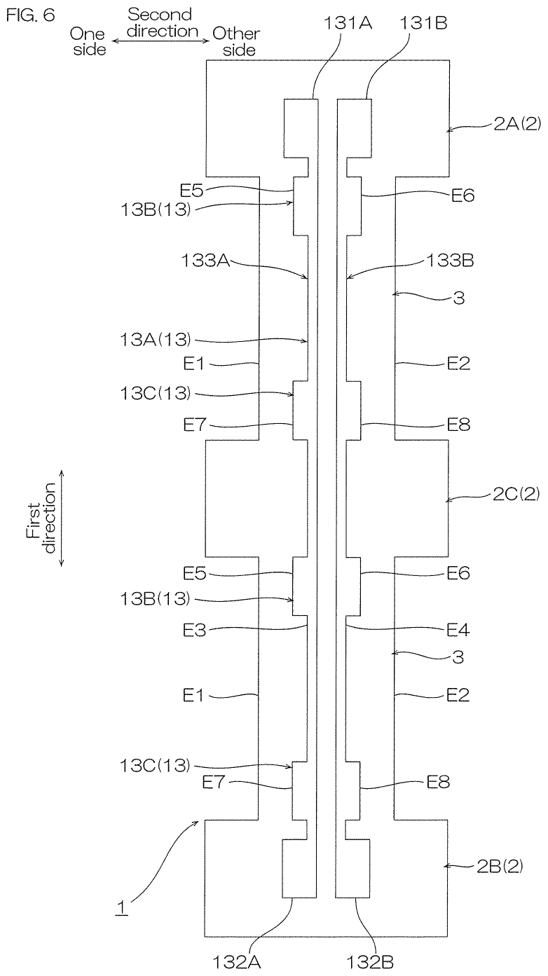

In this case, the first portion 13B of the conductive pattern 13 includes a dummy wiring 133C disposed on one side of the wiring 133A in the second direction and a dummy wiring 133D disposed on the other side of the wiring 133A in the second direction. The fifth end edge E5 of the first portion 13B is the one-side end edge of the dummy wiring 133C in the second direction, and the sixth end edge E6 of the first portion 13B is the other-side end edge of the dummy wiring 133D in the second direction.
(4) The wiring circuit board 1 may also have three or more support portions 2. For example, as shown in FIG. 6, the wiring circuit board 1 may also have a third support portion 2C in addition to the first support portion 2A and the second support portion 2B described above. In this case, the wiring circuit board 1 has the plurality of wiring portions 3A and 3B.

Each of the wirings 133A and 133B extends from the first support portion 2A to the second support portion 2B through the third support portion 2C. A middle portion of each of the wirings 133A and 133B is disposed in the third support portion 2C.

The third support portion 2C is disposed between the first support portion 2A and the second support portion 2B in the first direction. In other words, the third support portion 2C is disposed between the first support portion 2A and the second support portion 2B in the first direction. The third support portion 2C supports the other end portion of the wiring portion 3A, and one end portion of the wiring portion 3B. The wiring portions 3A and 3B have the same structure as the wiring portion 3 of the first embodiment.

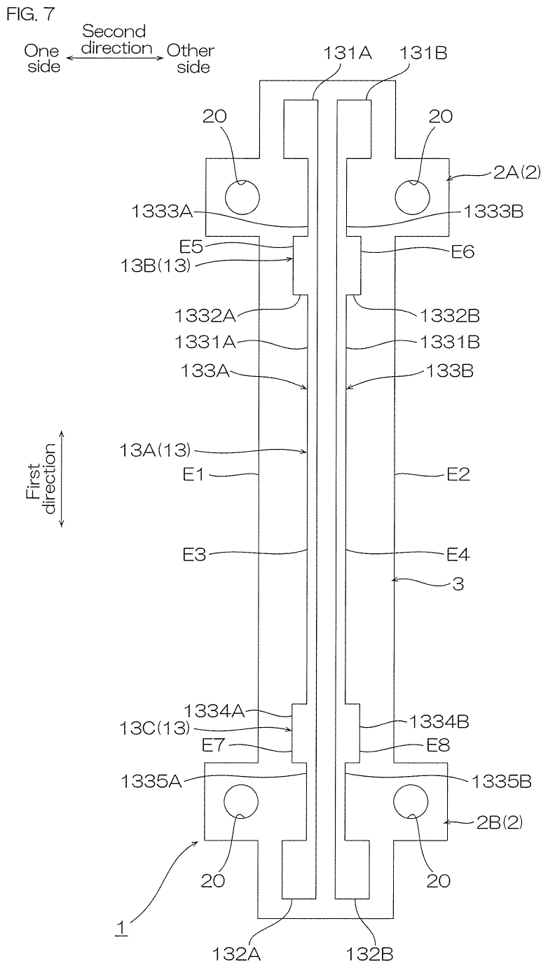

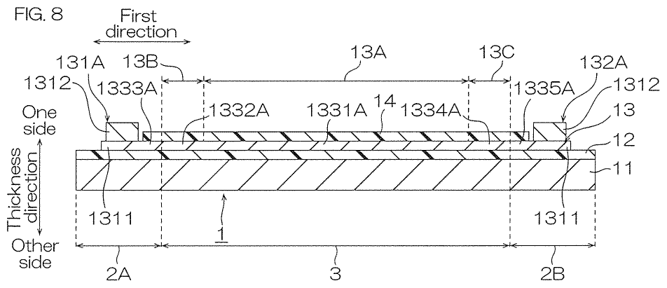

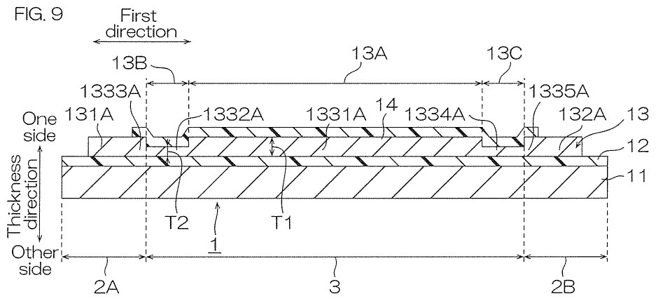

In this modified example, the middle portions of the wirings 133A and 133B can be supported by the third support portion 2C.
(5) As shown in FIG. 7, the terminals 131A and 131B may also not be disposed in the first support portion 2A. The first support portion 2A may be also disposed at a position different from the terminals 131A and 131B in the first direction. The first support portion 2A may be also disposed between the terminals 131A and 131B, and the wiring portion 3 in the first direction. The first support portion 2A may be also disposed away from the terminals 131A and 131B in the first direction. The terminals 132A and 132B may also not be disposed in the second support portion 2B. The second support portion 2B may be also disposed at the position different from the terminals 132A and 132B in the first direction. The second support portion 2B may be also disposed between the terminals 132A and 132B, and the wiring portion 3 in the first direction. The second support portion 2B may be also disposed away from the terminals 132A and 132B in the first direction. Each of the first support portion 2A and the second support portion 2B may also have a through hole 20. A fixture such as screw and pin passes through the through hole 20.
(6) The terminal 131A may also have a plurality of conductive layers. Specifically, as shown in FIG. 8, the terminal 131A may also have a first conductive layer 1311 and a second conductive layer 1312. The first conductive layer 1311 is disposed on the first insulating layer 12. The wiring 133A is connected to the first conductive layer 1311. As the material for the first conductive layer 1311, for example, the same material as the conductive pattern 13 described above is used. The second conductive layer 1312 is disposed on the first conductive layer 1311. The second conductive layer 1312 may be also made of the same material as the first conductive layer 1311. The second conductive layer 1312 may be also made of a material different from the first conductive layer 1311 (for example, solder).
(7) As shown in FIG. 9, a thickness T2 of the first portion 13B and the thickness of the second portion 13C may be also thinner than a thickness T1 of the main body portion 13A.

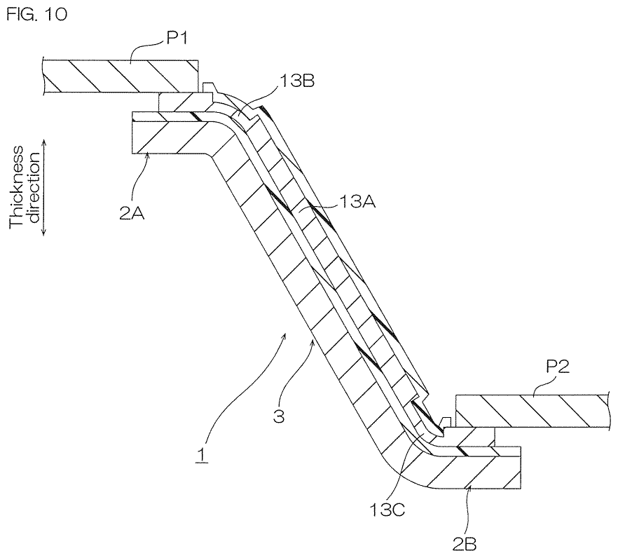

In this modified example, as shown in FIG. 10, when the first portion 13B and the second partial 13C are bent, it is possible to reduce a bending moment applied to the first portion 13B and the second portion 13C.

As a result, it is possible to suppress the crack in the conductive pattern 13 in the vicinity of the end portion of the wiring portion 3.
(8) In the above-described modified examples (1) to (7), the same function and effect as that of the first embodiment can be obtained.

### 5. Second Embodiment

A second embodiment is described. In the second embodiment, the same reference numerals are provided for members corresponding to each of those in the first embodiment, and their detailed description is omitted.

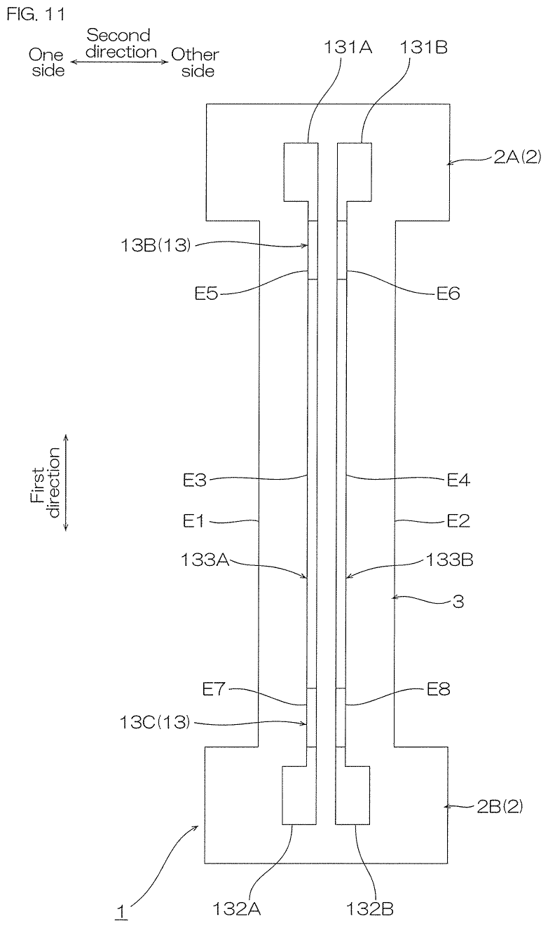

In the second embodiment, unlike the first embodiment, as shown in FIG. 11, the fifth end edge E5 of the first portion 13B is disposed at the same position as the third end edge E3 of the main body portion 13A in the second direction. Further, the sixth end edge E6 of the first portion 13B is also disposed at the same position as the fourth end edge E4 of the main body portion 13A in the second direction.

In the second embodiment, the thickness T2 of the first portion 13B and the thickness of the second portion 13C are thinner than the thickness T1 of the main body portion 13A in the same manner as the modified example (7) of the above-described first embodiment.

Therefore, it is possible to reduce the bending moment applied to the first portion 13B and the second portion 13C.

As a result, it is possible to suppress the crack in the conductive pattern 13 in the vicinity of the end portion of the wiring portion 3.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

A wiring circuit board of the present invention is available in connection of electronic components.

### DESCRIPTION OF REFERENCE NUMERALS

1 Wiring circuit board
2A First support portion
2B Second support portion
3 Wiring portion
11 Metal support layer
12 First insulating layer (one example of insulating layer)
13 Conductive pattern
13A Main body portion
13B First portion
13C Second portion
133A Wiring (first wiring)
133B Wiring (second wiring)
C Center
D11 Interval
D12 Interval
E1 First end edge
E2 Second end edge
E3 Third end edge
E4 Fourth end edge
E5 Fifth end edge
E6 Sixth end edge
E7 Seventh end edge
E8 Eighth end edge
W1 Width
W2 Width
W3 Width

1. A wiring circuit board comprising:
a wiring portion extending in a first direction, and
a first support portion supporting one end portion of the wiring portion, wherein
the wiring portion has a metal support layer, a conductive pattern disposed on one side of the metal support layer in a thickness direction of the metal support layer, and an insulating layer disposed between the metal support layer and the conductive pattern in the thickness direction;
the metal support layer has
a first end edge of a one-side end edge and a second end edge of another side end edge in a second direction perpendicular to both the thickness direction and the first direction;
the conductive pattern has
a main body portion disposed away from the first support portion in the first direction and having a third end edge of the one-side end edge and a fourth end edge of the other-side end edge in the second direction, and
a first portion disposed between the first support portion and the main body portion in the first direction and connected to the first support portion and having a fifth end edge of the one-side end edge and a sixth end edge of the other-side end edge in the second direction;
the third end edge of the main body portion is disposed between a center of the metal support layer and the first end edge of the metal support layer in the second direction; and
the fifth end edge of the first portion is disposed between the third end edge and the first end edge in the second direction.

2. The wiring circuit board according to claim 1, wherein
the fourth end edge of the main body portion is disposed between the center of the metal support layer and the second end edge of the metal support layer in the second direction, and
the sixth end edge of the first portion is disposed between the fourth end edge and the second end edge in the second direction.

3. The wiring circuit board according to claim 1, wherein
the conductive pattern has a wiring, and
a width of the wiring in the first portion is wider than the width of the wiring in the main body portion.

4. The wiring circuit board according to claim 1, wherein
the conductive pattern has
a first wiring and
a second wiring disposed spaced from the first wiring in the second direction, and
an interval between the first wiring and the second wiring in the first portion is wider than the interval between the first wiring and the second wiring in the main body portion.

5. The wiring circuit board according to claim 1, wherein
a width of each of the first wiring and the second wiring in the first portion is wider than the width of each of the first wiring and the second wiring in the main body portion.

6. The wiring circuit board according to claim 1, wherein
a thickness of the first portion is thinner than the thickness of the main body portion.

7. The wiring circuit board according to claim 1 further comprising:
a second support portion supporting the other end portion of the wiring portion, wherein
the conductive pattern further has
a second portion disposed between the second support portion and the main body portion in the first direction and connected to the second support portion and having a seventh end edge of the one-side end edge and an eighth end edge of the other-side end edge in the second direction; and
the seventh end edge of the first portion is disposed between the third end edge and the first end edge in the second direction.

8. A wiring circuit board comprising:
a wiring portion extending in a first direction and
a first support portion supporting one end portion of the wiring portion in the first direction, wherein
the wiring portion has an insulating layer and a conductive pattern disposed on one side of the insulating layer in a thickness direction of the insulating layer;
the conductive pattern has
a main body portion disposed away from the first support portion in the first direction, and
a first portion disposed between the first support portion and the main body portion in the first direction and connected to the first support portion; and
a thickness of the first portion is thinner than the thickness of the main body portion.

9. The wiring circuit board according to claim 8 further comprising:
a second support portion supporting the other end portion of the wiring portion, wherein
the conductive pattern further has
a second portion disposed between the second support portion and the main body portion in the first direction and connected to the second support portion; and
the thickness of the second portion is thinner than the thickness of the main body portion.
